(19) United States
(12) Patent Application Publication
(10) Pub. No.: US 2023/0171857 A1
(43) Pub. Date: Jun. 1, 2023

(54) ELECTROLUMINESCENT LIGHT SYSTEM

(71) Applicant: Nicholas Peter HART, Latham (AU)

(72) Inventor: Nicholas Peter HART, Latham (AU)

(21) Appl. No.: 17/920,333

(22) PCT Filed: Apr. 21, 2021
(86) PCT No.: PCT/AU2021/050355

§ 371 Date: Oct. 20, 2022

(30) Foreign Application Priority Data
Apr. 21, 2020 (AU) 2020901257

(51) Int. Cl. H05B 33/10; C09D 5/24; C09D 5/22; C09D 5/00

(52) U.S. Cl. CPC H05B 33/10; C09D 5/24; C09D 5/22; C09D 5/002

(57) ABSTRACT

The present invention relates to an improved process for the application of an electroluminescent light system. The present invention is also directed to an electroluminescent light system prepared by the process.

### TECHNICAL FIELD

The present disclosure relates generally to a process for the application of an electroluminescent light system.

### BACKGROUND

Electroluminescent technology has been known since the 1930s and there have been many developments to date. Traditionally, electroluminescent light systems were produced via blade coating or processes that were suited to relatively planar systems. However, since the 2010s EL technology has developed into a sprayable process, allowing for EL light systems to be applied to complex topologies, such as convex, concave and reflexed surfaces.

Electroluminescent light systems are generally sprayed on to a suitable substrate using a spray conformal process. Traditional spray conformal processes and paints are effective yet inherently unreliable. As an example, aqueous-based paints in multilayer systems cannot be sanded between coats and result in uncontrollable, uneven orange peel finishes, making them difficult paints to work with. Aqueous-based paints used for electroluminescent light systems can be relatively soft, reducing the stability of the system.

Existing spray conformal aqueous-based processes also require enhanced voltages and frequencies (above the optimal voltage and frequency 70-150V AC 400-800 Hz) to achieve effective brightness, which ultimately reduces the phosphor half-life. Traditionally, spray conformal processes are performed under a UV light source and this may cause damage to human eyes and excessive UV radiation has been associated with cancer, such as skin cancer.

Existing aqueous-based paints suitable for electroluminescent light systems are very expensive, take a long time to cure and require a great amount of skill to apply evenly. Spray conformal processes often use PEEDOT/PSS as the conductive clear coat. PEEDOT/PSS is difficult to apply, and being the only aqueous-based layer, does not adhere well to the surrounding layers.

Spray conformal processes use normal high volume low pressure (HVLP) spray painting systems that are prone to contamination and require specific environmental conditions.

Spray conformal processes generally do not atomise the particles with a charge to ensure an even coating of the multi layers of supersaturated suspended particles. Traditionally, spray conformal processes are not performed in a heated environment and nor are the materials heated, resulting in long curing times. Spray conformal processes are also subject to expanding and retracting molecules of air and cavitation as the temperatures changes throughout the system.

It is desired to address or ameliorate one or more of the disadvantages or limitations highlighted above, or to at least provide a useful alternative.

### SUMMARY

Provided herein is a process for the application of an electroluminescent light system to a substrate comprising:

selecting a substrate;

optionally applying an insulting primer layer to the substrate;

affixing a first electrical connection to the substrate or primer layer;

applying a backplane layer to the substrate or primer layer and the first electrical connection;

applying a dielectric layer to the backplane layer;

applying a phosphor layer to the dielectric layer;

affixing a second electrical connection to the phosphor layer;

applying a GPI anchor coating to the phosphor layer and second electrical connection;

applying a substantially transparent electrically conductive film layer to the GPI anchor coating; and

applying an encapsulating layer to the electroluminescent light system;

the phosphor paint layer being excitable upon application of an electric current between the backplane layer and the electrically conductive film layer such that the phosphor layer emits electroluminescent light.

Provided herein is an electroluminescent light system prepared by the process of the invention.

These and other aspects of the present invention will become more apparent to the skilled addressee upon reading the following detailed description in connection with the accompanying examples and claims.

### BRIEF DESCRIPTION OF THE DRAWINGS

Some embodiments of the present invention are hereinafter described, by way of example only, with reference to the accompanying drawings, wherein:

FIG. 1 is a schematic layer diagram of an electroluminescent light system according to an embodiment of the invention;

FIG. 2 is a flow diagram for a process for the application of an electroluminescent light system according to an embodiment of the invention;

FIG. 3 is a flow diagram of a process for the preparation of an electrical connection according to an embodiment of the invention;

FIG. 4 is a schematic layer diagram of an electroluminescent light system applied to a clear substrate according to an embodiment of the invention; and

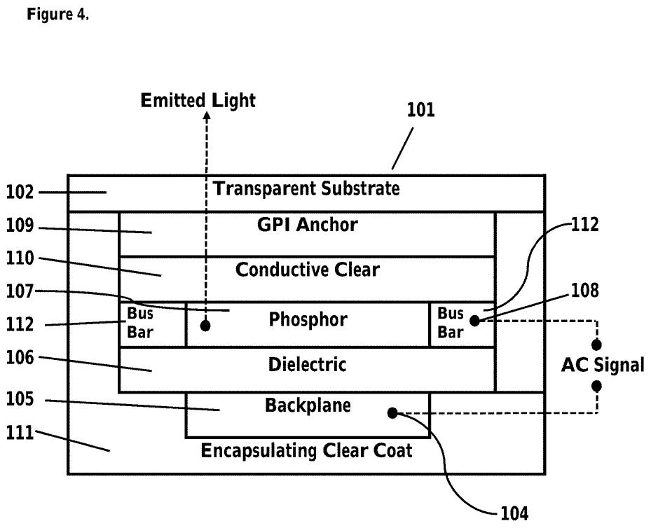

FIG. 5 is a schematic layer diagram of a layered electroluminescent light according to an embodiment of the invention.

### DETAILED DESCRIPTION

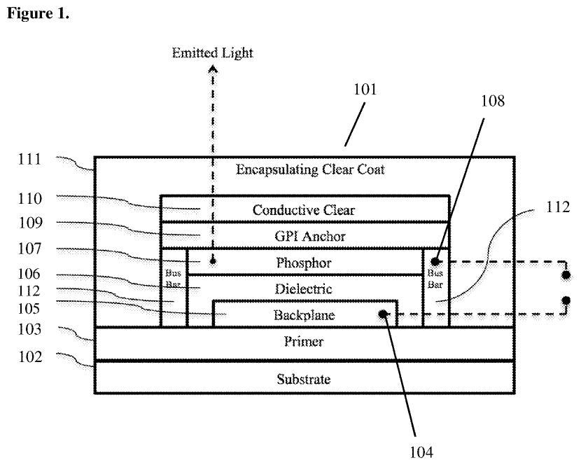

The general arrangement of the electroluminescent light system 101 of the invention is illustrated in FIG. 1. The electroluminescent light system 101 comprises a substrate 102, a primer layer 103, a first electrical connection 104, a backplane layer 105, a dielectric layer 106, a phosphor layer 107, a second electrical connection 108, one or more bus bar layers 112, a GPI anchor coating 109, a clear electrically conductive layer 110, and an encapsulating clear coat 111.

Embodiments described herein provide a process for the application of an electroluminescent light system 101 to a substrate 102.

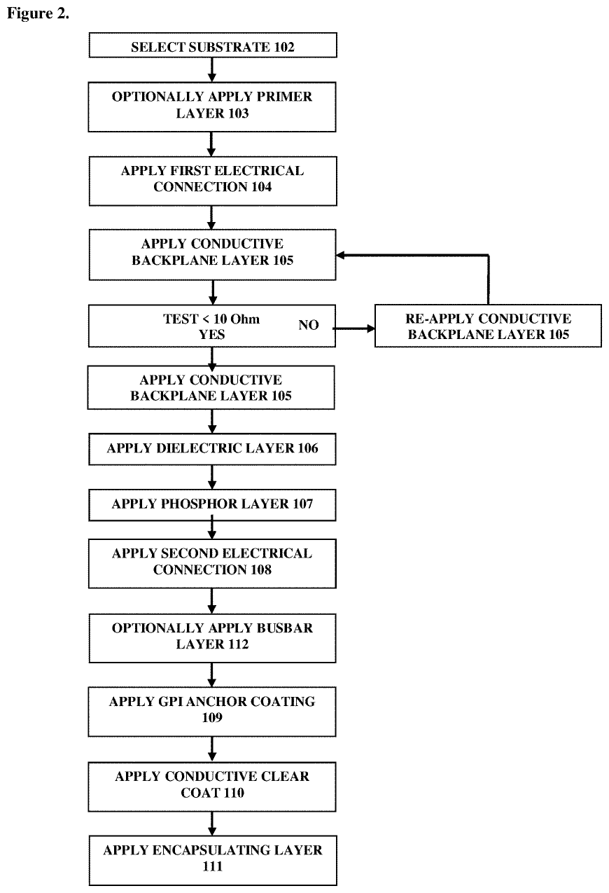

As shown in FIG. 2, the process comprises:
selecting a substrate 102;
optionally applying an insulting primer layer 103 to the substrate 102;
affixing a first electrical connection 104 to the substrate 102 or primer layer 103;
applying a backplane layer 105 to the substrate 102 or primer layer 103 and the first electrical connection 104;
applying a dielectric paint layer 106 to the backplane layer 105;
applying a phosphor layer 107 to the dielectric layer 106;
affixing a second electrical connection 108 to the phosphor layer 107;
applying a GPI anchor coating 109 to the phosphor layer 107 and second electrical connection 108;
applying a substantially transparent electrically conductive layer 110 to the GPI anchor coating 109; and
applying an encapsulating layer 111 to the electroluminescent light system 101;
the phosphor layer 107 being excitable upon application of an electric current between the backplane layer and the electrically conductive film layer such that the phosphor layer emits electroluminescent light.

The process according to the invention includes the application of a glycosylphosphatidylinositol (GPI) anchor coating 109 to the phosphor layer 107 and second electrical connection 108 before the substantially transparent electrically conductive layer 110 is applied. The GPI anchor coating 109 serves to anchor the PEEDOT/PSS conductive layer 110 to the electroluminescent light system 101. It also increases the electrical conductivity of the electroluminescent light system 101 by up to 3 orders of magnitude compared to PEEDOT/PSS alone.

In one embodiment of the invention, the optional insulting primer layer 103, backplane layer 105, dielectric layer 106, phosphor layer 107, GPI anchor coating109, electrically conductive film layer 110 and encapsulating clear coat 111 are applied to a substrate 102 by spray conformal coating.

In another embodiment, the optional insulting primer layer 103, backplane layer 105, dielectric layer 106, phosphor layer 107, GPI anchor coating 109 and electrically conductive layer 110 are printed on to a substrate 102.

The substrate 102 may be a surface on any suitable item upon which the electroluminescent light system is to be applied. The substrate 102 may be made of any material, may be conductive or non-conductive and may be rigid or flexible. The substrate 102 may have any desired shape including convex, concave, reflexed and combinations thereof. In some embodiments, the substrate 102 may be a transparent material such as glass or plastic.

Optionally, an insulting primer layer 103 is first applied to the substrate 102. The primer layer 103 may be a non-conductive solvent-based paint coating. The primer layer 103 serves to electrically insulate the substrate 102 from the subsequent conductive and semi-conductive layers discussed below.

The primer layer 103 also usefully promotes adhesion between the substrate 102 and the subsequent layers. A suitable primer may be, but is not limited to, a solvent-based binder, for example, D895 Colour Blender from PPG®. As would be understood, the primer layer 103 is applied at a thickness recommended by a supplier.

Advantageously, the same solvent-based binder may be used for the primer layer 103, backplane layer 105, dielectric layer 106, phosphor layer 107 and encapsulating layer 111 reducing costs, improving the application process and allowing for sanding in between layers if necessary.

A first electrical connection 104 is then affixed to the substrate 102 or primer layer 103. The first electrical connection 104 may be connected to the substrate 102 or primer layer 103 by conventional means including soldered connections, adhesive cooper tape, clip arrangements, threaded fasteners and the like. The connection points may be covered by heat-shrink silicone tubes for insulation and protection against water.

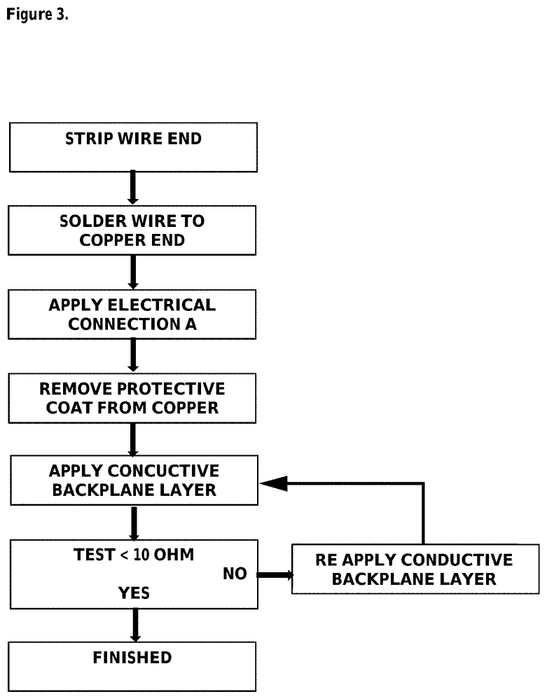

As illustrated in FIG. 3, in one embodiment the first electrical connection 104 may be prepared by striping the protective covering from the end of an electrical conduit, such as a wire. The exposed wire is then soldered to adhesive copper tape that, in turn, is adhered to the substrate 102 or primer layer 103. The first electrical connection 104 may be lightly sanded to remove any protective coating from the copper tape before application of the backplane layer 105 to enhance the electrical connection with the backplane layer 105.

A conductive backplane layer 105 is then applied to the substrate 102 or primer layer 103. The conductive backplane layer 105 is in contact with a first electrical connection 104 and acts as an electrical conductor. The conductive backplane layer 105 may be a suitable spray conductive material that is masked or stenciled over the substrate 102 or primer layer 103 to form a bottom electrode shape of the electroluminescent light system 101. Suitable spray conductive materials include commercially available paints comprising metallic additives such as silver or copper, or solvent-based paints mixed with fine metallic particles such as copper and/or silver.

Preferably, the electrically conductive backplane layer 105 has a relatively low resistance to minimise voltage gradients across its surface to allow for the optimal operation of the electroluminescent light system 101 (i.e., sufficient lamp brightness and uniformity). As shown in FIG. 3, in one embodiment the conductive backplane layer 105 is applied and tested until its resistance is at <10 Ohms along the longest area.

In one embodiment, the backplane layer 105 is a highly conductive generally opaque material comprising a solvent-based binder such as, but not limited to, D895 Colour Blender from PPG® mixed with 20% by weight of a conductive powder comprising 3% silver and 97% copper. Reducer may be added to the mixture to achieve a consistency suitable for application.

In another embodiment, the conductive backplane layer 105 is an electrically conductive, generally clear layer such as, without limitation, PEDOT/PSS PH1000 conductive polymer available from Heraeus Clevios GmbH of Leverkusen, Germany. A suitable solution may be prepared by adding 5% by weight of dimethyl sulfoxide (DMSO, 99.99%) to a solution of PEDOT:PSS and sonicating the solution overnight or for around 14 hours. Isopropyl alcohol (99.99%) is then added to the solution at a ratio of 1:1. This solution allows for more coverage with less product and allows for atomisation of the solution for spray application resulting in enhanced brightness and a more even transparent film layer.

The conductive backplane layer 105 may also be a metal plating wherein a suitable conductive metal material is applied to a non-conductive substrate using any suitable process. Exemplary metal plating processes include, but are not limited to, electroplating, metalizing, vapour deposition, chroming and sputtering.

In one embodiment, the conductive backplane layer 105 is applied at a depth of 100-500 microns.

A dielectric layer 106 is then applied to the backplane layer 105. The dielectric layer 106 serves to provide an insulating barrier between the backplane layer 105 and the phosphor layer 107, a busbar layer 112 and clear conductive layer 110. The dielectric layer 106 is therefore an electrically non-conductive layer. The dielectric layer 106 also serves to enhance the electromagnetic field generated between the backplane layer 105 and clear conductive layer 110. The dielectric layer 106 may comprise a material having high dielectric constant properties such as a titanate (e.g., barium titanate, BaTiO₃), an oxide, a niobate, an aluminate, a tantalate and a zirconate material encapsulated within a polymer or solvent-based binder (e.g., D895 Colour Blender from PPG®).

In one embodiment, the dielectric layer 106 comprises a solvent-based binder such as D895 Color Blender from PPG® mixed with 20% by weight BaTiO to form a supersaturated suspension. Reducer may be added to the mixture to achieve a consistency suitable for application. In one embodiment, the solvent-based binder and reducer are mixed in a ratio of 1:1.5.

In one embodiment, the reducer is a suitable solvent such as isopropyl alcohol. In another embodiment, the reducer is an ethanol based solvent. In one embodiment, the reducer is present in an amount of 5-80% by weight of the BaTiO₃.

In one embodiment, the dielectric layer 106 is applied to a depth of 40-100 microns. In another embodiment the dielectric layer 106 is applied in 2 or 3 successive coats at a thickness of 40-100 microns to ensure even distribution of the BaTiO₃. Excessive build-up of material or unevenness of application may result in pooling, patchiness, running or drooping of the dielectric layer 106. Application of the dielectric layer by spray conformal coating under an atmosphere of heated, ionised nitrogen as explained below can help to eliminate these unwanted results.

A phosphor layer 107 is next applied to the dielectric layer 106. The phosphor layer 107 is a semi-conductive material typically comprised of metal-doped Zinc Sulfide (ZnS) held in a super-saturated suspension within a carrier. The carrier may be a solvent-based binder, for example, D895 Colour Blender from PPG®. When excited by the presence of an alternating electrostatic field generated by an AC signal, the metal-doped ZnS absorbs energy from the field and in turn re-emits it as a visible-light photon upon returning to its ground state. While the metal-doped ZnS phosphor layer 107 is technically a semiconductor, when encapsulated within a co-polymer matrix, it effectively provides a further insulating layer between the backplane layer 105 and the second electrical connection 108 and bus bar layers 112.

In one embodiment, phosphor layer 107 comprises a solvent-based binder such as D895 Color Blender from PPG® mixed with ZnS doped with at least one of silver, cooper and manganese, for example, ZnS:Ag, ZnS:Cu, ZnS:Mn, etc. to form a supersaturated suspension. In one embodiment the doped ZnS comprises 20% by weight of the mixture. Reducer may be added to the mixture to achieve a consistency suitable for application. In one embodiment, the solvent-based binder and reducer are mixed in a ratio of 1:1.5.

In one embodiment, the phosphor layer 107 is applied at a thickness of 60-120 microns.

Application of the phosphor layer 107 may be carried out under an ultraviolet (UV) radiation source such as a long-wave ultraviolet source in an otherwise darkened area. Upon application, the phosphor layer glows brightly under UV radiation creating a visual aid to improve uniformity of application.

In another embodiment, the substrate is illuminated by a blue LED light source in an otherwise darkened area during application of the phosphor layer. Similar to a UV radiation source, the phosphor layer glows brightly upon application under a blue LED light source creating a visual aid to improve uniformity of application. Beneficially, use of a blue LED light source removes any risk of potential harm caused by UV radiation.

A second electrical connection 108 is affixed to the phosphor layer 107. As with the first electrical connection 104, the second electrical connection 108 may be connected to the phosphor layer by conventional means including soldered connections, adhesive cooper tape, clip arrangements, threaded fasteners and the like. The connection points may be covered by heat-shrink silicone tubes for insulation and protection against water. In one embodiment, the second electrical connection comprises an electrical conduit such as a wire soldered to adhesive copper tape that is adhered to the phosphor layer 107. The second electrical connection may be prepared as explained above for the first electrical connection.

A busbar layer 112 may then be applied to the phosphor layer 107. The busbar layer 112 acts to provide a relatively low-impedance strip of conductive material similar to the materials suitable for the clear conductive layer 110 described below. Typically, the busbar layer 112 is applied to the periphery of the backplane layer 105 but so as to not overlap the backplane layer 105.

Suitable spray conductive materials for the busbar layer 112 include commercially available paints comprising metallic additives such as silver or copper, or solvent-based paints mixed with fine metallic particles including copper and/or silver.

In one embodiment, the busbar layer 112 comprises a solvent-based binder, such as D895 Colour blender from PPG®, mixed with 3% silver 97% copper powder. In one embodiment, the solvent-based binder is mixed with 20% by weight of 3% silver 97% copper powder. Reducer may be added to the mixture to achieve a consistency suitable for application. In one embodiment, the solvent-based binder and reducer are mixed in a ratio of 1:1.5.

A GPI anchor coating 109 is next applied to the phosphor layer 107, optional busbar layer 112 and second electrical connection 108. As mentioned above, the GPI anchor coating 109 serves as a rigid under-layer anchoring the following conductive layer 110 to the electroluminescent light light system 101. The GPI anchor coating 109 also increases the electrical conductivity of the electroluminescent light system 101 by up to 3 orders of magnitude compared to PEEDOT/PSS alone. The GPI anchor coating 109 comprises between 2% and 20%, such as between 3% and 15%, between 4% and 10%, between 5% and 8%, of a suitable lipid such as glycerine in an aqueous solvent. In one embodiment, the aqueous solvent is water. In a preferred embodiment, the water is deionised water.

In one embodiment, the GPI anchor coating comprises 5% glycerine in deionised water.

A substantially transparent electrically conductive layer 110 is applied evenly to the GPI anchor coating 109. The electrically conductive layer 110 is both highly electrically conductive and generally transparent to light.

The clear electrically conductive layer 110 may comprise conductive polymers such as poly(3,4-ethylenedioxythiophene)polystyrene sulfonate (PEDOT:PSS), indium tin oxide (ITO), antimony tin oxide (ATO), and solvents such as dimethyl sulfoxide (DMSO). The clear electrically conductive layer 110 may comprise the product CLEVIOS™ (Heraeus Clevios GmbH of Leverkusen, Germany), a transparent and flexible polymer that may be diluted in a suitable solvent such as isopropyl alcohol (IPA) acting as a thinner/drying agent. Suitable PEDOT:PSS solutions are explained above for the conductive backplane layer.

CLEVIOS™ conductive polymers exhibit relatively high efficacy and are relatively environmentally benign. In addition, CLEVIOS™ conductive polymers are based on a 20 styrene co-polymer and thus provides a ready mechanism for chemical cross linking/mechanical bonding with the underlying phosphor layer.

The clear electrically conductive layer 110 may be applied by spray conformal coating with a power source connected to the first 104 and second electrical connections 108. In this way, illumination of the phosphor layer 107 can be visually monitored during application and sufficiency of the thickness and efficiency of the clear conductive layer 110 can be monitored to allow the electroluminescent light system 101 to emit light in the desired manner. The number of coats required may be determined by the uniformity and distribution of the material, as well as specific local conductivity as determined by the physical distance between any gaps in the busbar 112.

In one embodiment, the clear electrically conductive layer 110 is applied at a thickness of 5-20 microns.

An encapsulating layer 111 is then applied to the electroluminescent light system. The transparent encapsulating layer 111 acts to protect the other layers against environmental damage and may comprise a solvent-based paint or clear coat.

In one embodiment, the encapsulating layer 111 is an electrically insulating material applied over the electroluminescent light system, thereby protecting the lamp from external damage. The encapsulating layer 111 is preferably generally transparent to light emitted by the electroluminescent light system 101 and is chemically compatible with any materials that may be applied to the electroluminescent light system 101 and the surrounding substrate 102 to provide a mechanism for chemical and/or mechanical bonding with top-coating layer(s). The encapsulating layer 111 may be comprised of any number of aqueous, enamel or lacquer-based products. Suitable encapsulating layers 111 include, but are not limited to, clear polymers of suitable hardness to protect the electroluminescent light lamp from damage. The encapsulating layer 111 may also be a substantially clear laminate such as a transparent vinyl or plastic laminate.

As shown in FIG. 3, in one embodiment, the substrate 102 may be a transparent material such as glass or plastic and the electroluminescent light system 101 may be configured to emit light through the substrate 102. In such a system the clear conductive layer 110, busbar layer 112, phosphor layer 107, dielectric layer 106, conductive backplane layer 105 and encapsulating layer 111 are applied to the substrate in that order using the materials and methods described herein.

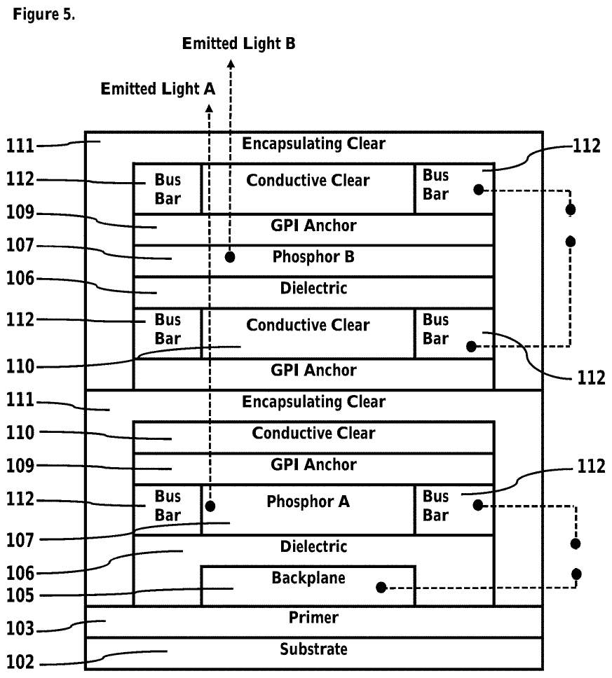

In another embodiment, the electroluminescent light system 101 may comprise two or more systems applied one above the other as illustrated in FIG. 5, the lower system emitting light through the entirety of the upper system. Such a system enables two independent light sources, for example, of different colours that can be switched electronically within one space.

Application of the electroluminescent light system 101 may be via spray conformal coating via suction and/or pressure feed type spray equipment that atomises the liquid material of each layer, mixes it with a gas such as air and coats the material on a surface. Such a process may include masking out an area on the substrate to which the electroluminescent light system 101 is to be applied. As mentioned above, the substrate 102 may have any desired shape including convex, concave, reflexed and combinations thereof. Using this process the electroluminescent light system 101 conforms to the shape of the substrate.

The insulting primer layer 103, backplane paint layer 105, dielectric paint layer 106, phosphor paint layer 107, GPI anchor coating 109, electrically conductive layer 110 and encapsulating layer 111 may be applied by spray conformal coating under an atmosphere of nitrogen. In one embodiment, the nitrogen may be heated, for example, to about 40° C., about 50° C., about 60° C., about 65° C., about 70° C., about 75° C., or about 80° C. In a preferred embodiment, the nitrogen is heated to about 70° C.

In one embodiment, the heated nitrogen is ionised. Suitable systems include the Nitrotherm® spray system. Using such a system is beneficial as the heated, ionised nitrogen does not react in any way with the layers of the electroluminescent light system 101. Heated, ionised nitrogen does not interfere with the particle matrix of each layer or the catalytic effect of evaporation during the curing process. As such, use of heated, ionised nitrogen increases conformity of the layers. Applying the layers in this way also greatly reduces impurities such as dust, oil or fumes and eliminates moisture in the lines of the spray equipment.

In another embodiment, the backplane layer 105, dielectric layer 106, phosphor layer 107, GPI anchor coating 109, and the electrically conductive layer 110 are applied to the substrate using a printer. The process may comprise designing the desired electroluminescent light system 101 in a vector based system such as Adobe Illustrator or other system that allows for the design of the different layers. The design is then sent to a suitable printer such as an inkjet printer that allows printing on a number of media.

Roland VersaWorks, for example, is a RIP print program that runs wide format printers. VersaWorks has dedicated swatch colours for cutting and custom colours. These can be dedicated to a custom ink cartridge and print head. Each layer in the electroluminescent light system 101 to be printed will have its own dedicated swatch colour linked to its own custom ink cartridge and print head.

Each layer in the electroluminescent light system will print separately at the correct micron size in the order. The printer may print out the layer/colour over a heating unit onto the substrate, the print will stop and dry, then feed back into the printer to print the next layer/colour and so on. The thickness (micron), number of passes, heating and drying time in between layers can be programed for each of the layers to tailor the process to meet the requirements for each layer.

The printing process may comprise the following steps:
1. Printing identification marks on the substrate with a standard ink colour such as black ink and the allowing for the ink to dry;
2. Removing the substrate from the printer;
3. Manually affixing the first 104 and second 108 electrical connections to the substrate;
4. Printing the busbar 112 and backplane layer 105 to the substrate and first and second electrical connection followed by a drying step;
5. Printing the dielectric layer 106 followed by drying;
6. Printing the phosphor layer 107 followed by drying;
7. Printing the GPI anchor coating 109 followed by drying;
8. Printing the conductive transparent layer 110 followed by drying; and
9. Removing the substrate from the printer and applying a laminated encapsulating layer 111.

Optional layers may be added to the laminate including stencils, tinting and full colour print.

In one embodiment, the printing software is programmed to print an outline for the first 104 and second 108 electrical connections on the substrate 102 or primer layer 103. After which, the printing will stop and the substrate 102 will exit the printer or otherwise be exposed so that the first 104 and second 108 electrical connections can be manually affixed to the material.

In another embodiment, the printer will be equipped to stamp adhesive copper first and 104 and second 108 electrical connections to the material at the appropriate time during the printing process.

Once printed, the first 104 and second 108 electrical connections are exposed for connection to a power source, for example, via a plug type connector or a spike type connector that are clamped over the first and second electrical connections.

In one embodiment, the substrate 102 used in the printing process is made from a polymer, for example, a vinyl polymer.

A power source is required to illuminate the electroluminescent light system 101. In one embodiment, the power source is a portable power source comprising one or more batteries such as replaceable AA 3v batteries. Alternatively, the power source may comprise one or more rechargeable batteries such as a rechargeable lithium-ion battery, for example, a rechargeable 3.7v 600 mAh battery, a rechargeable 3.7v 1000 mAh battery, a rechargeable 3.7v 1800 mAh battery, or a rechargeable 3.7v 3200 mAh battery.

An AC-DC inverter may also be electrically connected between the electroluminescent light system 101 and the power source. The voltage of the inverter may be in the range of 50v-150v, for example, 50v-120v, 50v-110v, 50v-100v, 50v-90v, 50v-80v, 50v-70v, 50v-60v. Preferably, the voltage of the inverter will be in the range of 50v-70v. The inverter 804 will operate at a frequency of 200 Hz-2,000 Hz, such as 300 Hz-2,000 Hz, 400 Hz-1,800 Hz, 500 Hz-1,800 Hz, 600 Hz-1,800 Hz, 700 Hz-1,800 Hz, 800 Hz-1,800 Hz. Preferably, the inverter 804 will operate at 700 Hz-1800 Hz.

A control switch may also be electrically connected between the electroluminescent light system 101 and the power source. A control switch turns the electroluminescent light system 101 on and off. The control switch may also control the electroluminescent light system 101 in different modes including off, continuously on, or on intermittently in a flashing fashion, e.g., by using a control switch with a timer integrated circuit chip or similar chip. In one embodiment the control switch is a magnetic reed switch.

A charging port may be electrically connected to the power source for ease of recharging the power source. Alternatively, the power source may be located in a storage box and said storage box may comprise a wireless charging receiver such as a Qi charging receiver or coil. The storage box may be manufactured from a durable material such as polycarbonate or acrylonitrile butadiene styrene or similar durable plastic.

The storage box may be a sealed unit comprising a power source, an inverter, a magnetic reed control switch, a wireless charging receiver, a safety cut-out circuit and optionally a LED status light. The storage box may protect against total duct ingress and be able to withstand extended immersion in water. In one embodiment, the storage box will have an immersion protection rating of 68 (IP68).

Interpretation

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Many modifications will be apparent to those skilled in the art without departing from the scope of the present invention.

1. A process for the application of an electroluminescent light system to a substrate comprising:
selecting a substrate;
optionally applying an insulting primer layer to the substrate;
affixing a first electrical connection to the substrate or primer layer;
applying a backplane layer to the substrate or primer layer and the first electrical connection;
applying a dielectric paint layer to the backplane layer;
applying a phosphor paint layer to the dielectric paint layer;
affixing a second electrical connection to the phosphor paint layer;
applying a GPI anchor coating to the phosphor paint layer and second electrical connection;
applying a substantially transparent electrically conductive film layer to the GPI anchor coating; and
applying an encapsulating layer to the electroluminescent light system;
the phosphor paint layer being excitable upon application of an electric current between the backplane layer and the electrode film layer such that the phosphor layer emits electroluminescent light.

2. The process according to claim 1, wherein the backplane layer, dielectric layer, phosphor layer and encapsulating layer are solvent-based paint layers.

3. The process according to claim 1 or 2, wherein the electrically conductive film layer is an aqueous-based paint layer.

4. The process according to any one of claims 1 to 3, wherein the insulting primer layer, backplane paint layer, dielectric paint layer, phosphor paint layer, GPI anchor coating, electrically conductive film layer and final clear coat are applied by spray conformal coating.

5. The process according to claim 4, wherein the insulting primer layer, backplane paint layer, dielectric paint layer, phosphor paint layer, GPI anchor coating, electrically conductive film layer and final clear coat are applied by spray conformal coating under an atmosphere of nitrogen.

6. The process according to claim 4 or 5, wherein the substrate is illuminated by a Blue LED light source or UV light source during application of the phosphor layer.

7. The process according to claim 6, wherein the substrate is illuminated by a Blue LED light source during application of the phosphor layer.

8. The process according to any one of claims 4 to 7, wherein each layer is applied using nitrogen as a carrier gas.

9. The process according to claim 8, wherein the nitrogen is ionised.

10. The process according to claim 8 or 9, wherein the nitrogen is heated to 70° C.

11. The process according to claim 1, wherein the backplane layer, dielectric layer, phosphor layer, GPI anchor coating, and the electrically conductive film layer are applied to the substrate using a printer.

12. The process according to claim 11, wherein the substrate is a vinyl substrate.

13. The process according to claim 11 or 12, wherein the encapsulating layer is a laminate layer.

14. The process according to any one of claims 1 to 13, wherein the electric current is provided by a portable power source comprising one or more batteries.

15. The process according to claim 14, wherein the batteries are rechargeable batteries.

16. An electroluminescent light system prepared by the process of any one of claims 1 to 15.
